(19) United States
(12) Patent Application Publication
(10) Pub. No.: US 2013/0105342 A1
(43) Pub. Date: May 2, 2013

(54) Earphone Case

(71) Applicant: Yasuhiro Yamamoto, Los Angeles, CA (US)

(72) Inventor: Yasuhiro Yamamoto, Los Angeles, CA (US)

(73) Assignee: EVER WIN INTERNATIONAL CORPORATION, City of Industry, CA (US)

(21) Appl. No.: 13/282,154

(22) Filed: Oct. 26, 2011

(51) Int. Cl. B65D 85/86; H05K 5/00

(52) U.S. Cl. 206/320; 206/726

(57) ABSTRACT

A compact and extremely slim case for securely holding a pair of compact earphones, their cables, and the audio plug. The earphone case is approximately the dimension of a standard credit card with a thickness approximately equivalent to the depth of an earphone. The earphone case securely encloses and holds a pair of earphones and the audio plug along with their cables securely wrapped inside the case. The earphone case is the slimmest possible case for a pair of compact earphones.

### BACKGROUND—FIELD OF INVENTION

The present invention relates generally to cases for earphones. More specifically, the present invention relates to a compact and slim case for securely holding a pair of earphones, their cables, and the audio plug.

### BACKGROUND—DESCRIPTION OF RELATED ART

Earphones are commonly used with portable electronic devices such as digital music players for personal enjoyment of the music without disturbing others around the listener. The earphones are usually used in pairs and are connected by thin cables to a small audio plug. The earphones are compact speakers that need to be protected when not in use. There has always been a desire to design a small compact case to protect and retain the earphones when they are not being used.

Prior designs are usually very thick and bulky. The thickness of the case is always substantially thicker than the depth of the earphones. No prior art design is of sufficient compactness and slimness to comfortably fit like a credit card in a men's wallet. Furthermore, most prior designs do not fully enclose the earphones to positively retain them within the case.

Most prior designs use a frictional retention method that may loosen their retention of the earphones after repeated use or release their retention due to shock from the case being dropped or impacted.

Arai et al. (U.S. Pat. No, 5,706,353) shows a tape recorder with 2 take-up units to retract cords from a pair of earphones. The earphones are held in holders with friction. It is a relatively complex and bulky unit with many moving parts and no enclosure to positively enclose and retain the earphones. The earphones can easily fall out of their holders, particularly after repeated use and wear of the friction points.

Lin (U.S. Pat. No. 5,887,720) shows a earphone case that is relatively thick and bulky with a relatively complex winding mechanism for the wires with several moving parts. The case is much thicker than the earphones due to the enclosure design and the winding mechanism.

Chang (U.S. Patent Publication Number US 2007/0154048) shows a protective case for an electronic device. The case encloses the electronic device and is provided with recess on its back to frictionally retain a pair of earphones and their plug. It is a relatively thick and bulky unit that is mainly for enclosing and protecting the electronic device. It does not positively enclose and retain the earphones. This holder design also will not securely retain the earphones, particularly after repeated insertion and removal of the earphones, which will wear down the frictional retaining points. The case is much thicker than the earphones due to the enclosure design for the electronic device.

Therefore, there is a need for a compact and slim earphone case that can be easily carries such as in a men's wallet. There is also a need for an earphone case that can securely retain the earphones without accidentally releasing them due to repeated insertion and removal of the earphones or dropping of the case.

### BRIEF SUMMARY OF THE INVENTION

The present invention is a compact and extremely slim case for securely holding a pair of compact earphones, their cables, and the audio plug. In the preferred embodiment, the earphone case is approximately the dimension of a standard credit card with a thickness approximately equivalent to the depth of an earphone. The earphone case is preferably made of a plastic material in the form of a one-piece clam-shell with no moving components. The earphone case securely encloses and holds a pair of earphones and the audio plug along with their cables securely wrapped inside the case. The present invention is the slimmest possible case for a pair of compact earphones.

### BRIEF DESCRIPTION OF THE DRAWINGS

FIG. 1 shows a perspective front view of the earphone case.

FIG. 2 shows a perspective rear view of the earphone case.

FIG. 3 shows the elevated front view of the earphone case.

FIG. 4 shows the top view of the earphone case.

FIG. 5 shows the elevated rear view of the earphone case.

FIG. 6 shows the right side view of the earphone case.

FIG. 7 shows the left side view of the earphone case.

FIG. 8 shows a perspective view of the empty interior of the earphone case.

FIG. 9 shows a perspective view of the interior of the earphone case with a pair of earphones, their cables, and the audio plug.

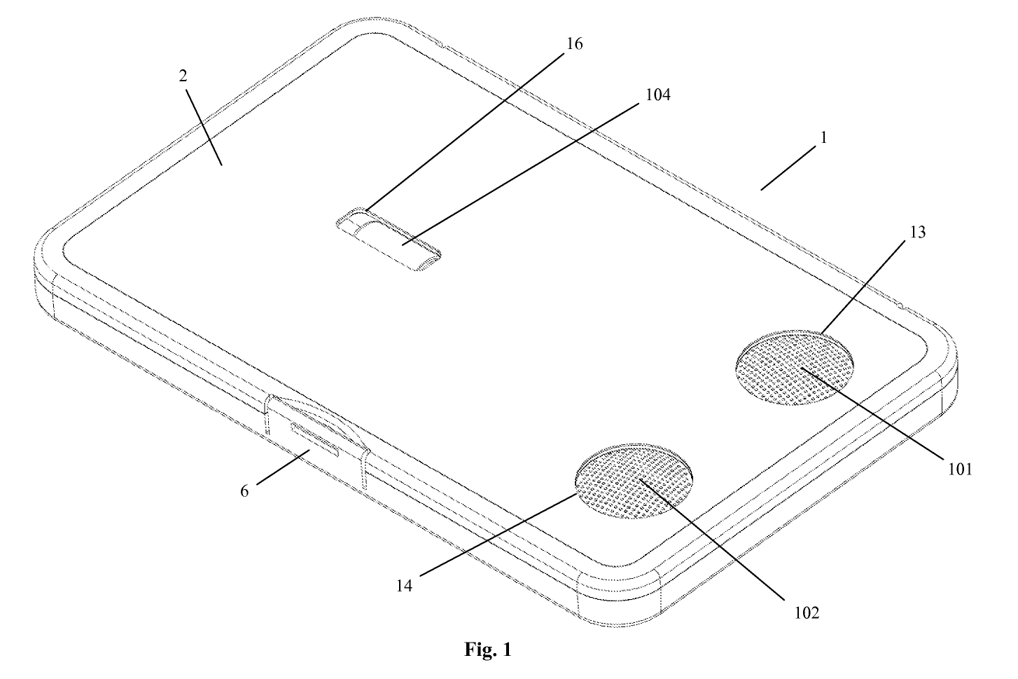

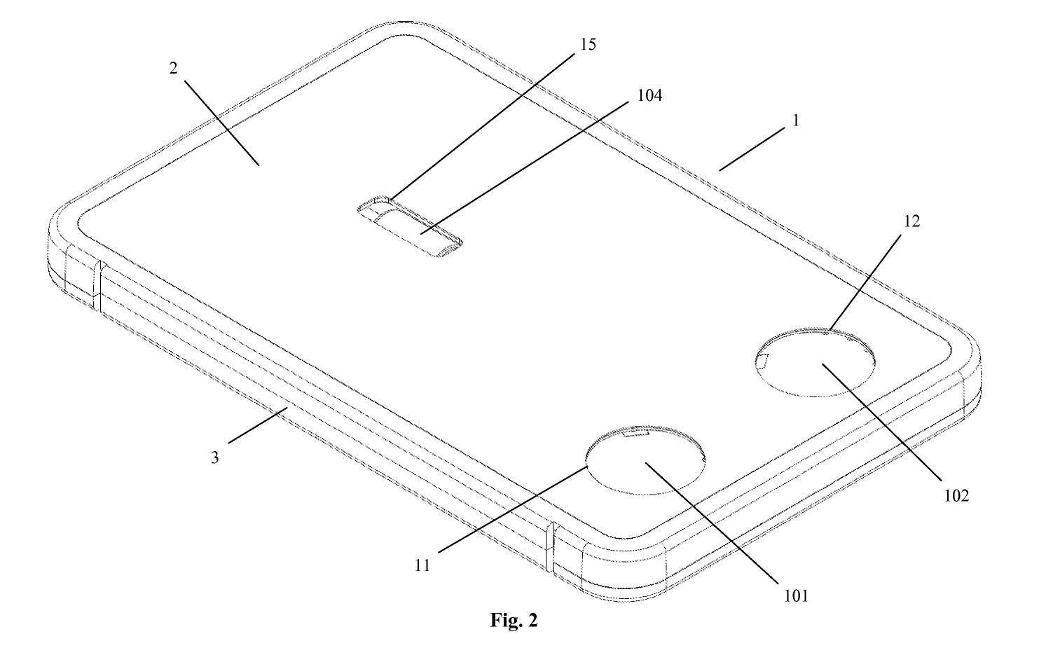

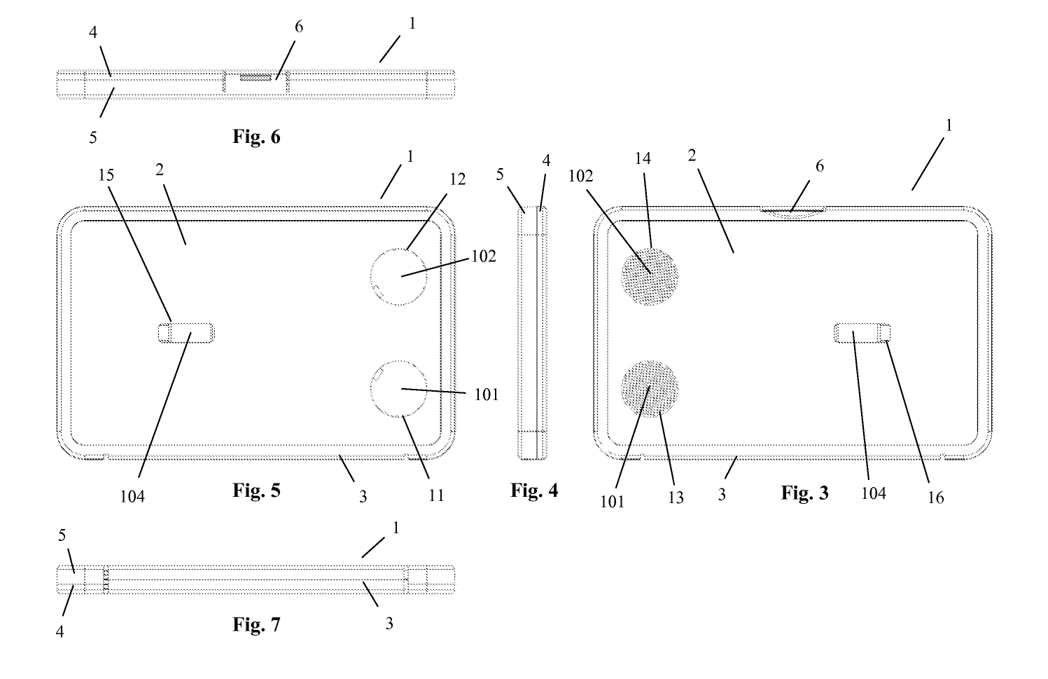

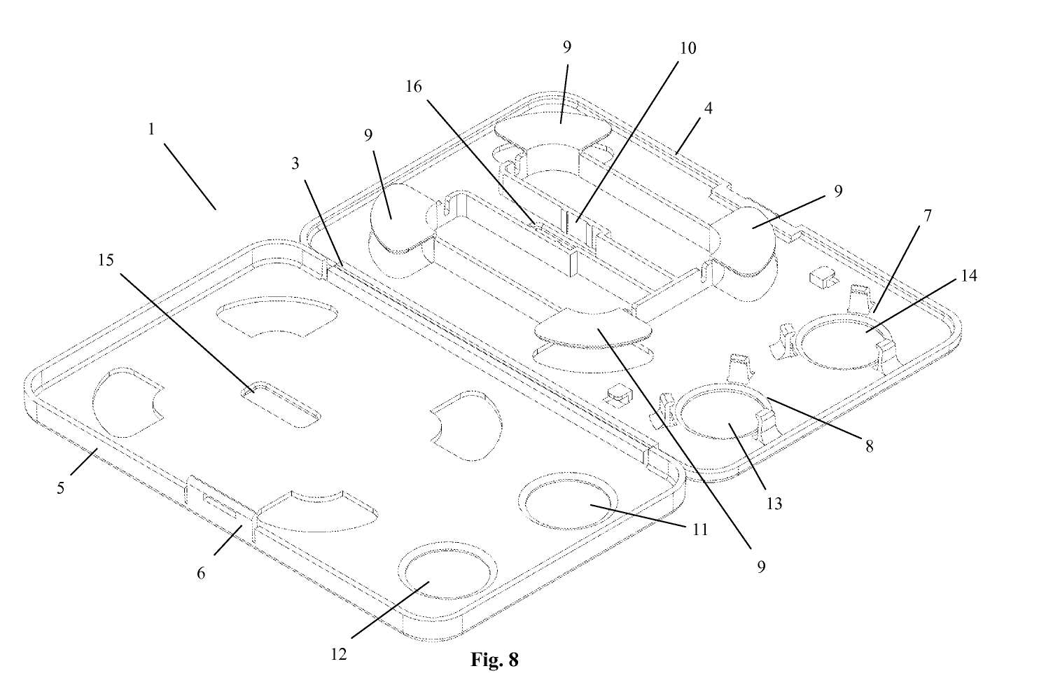

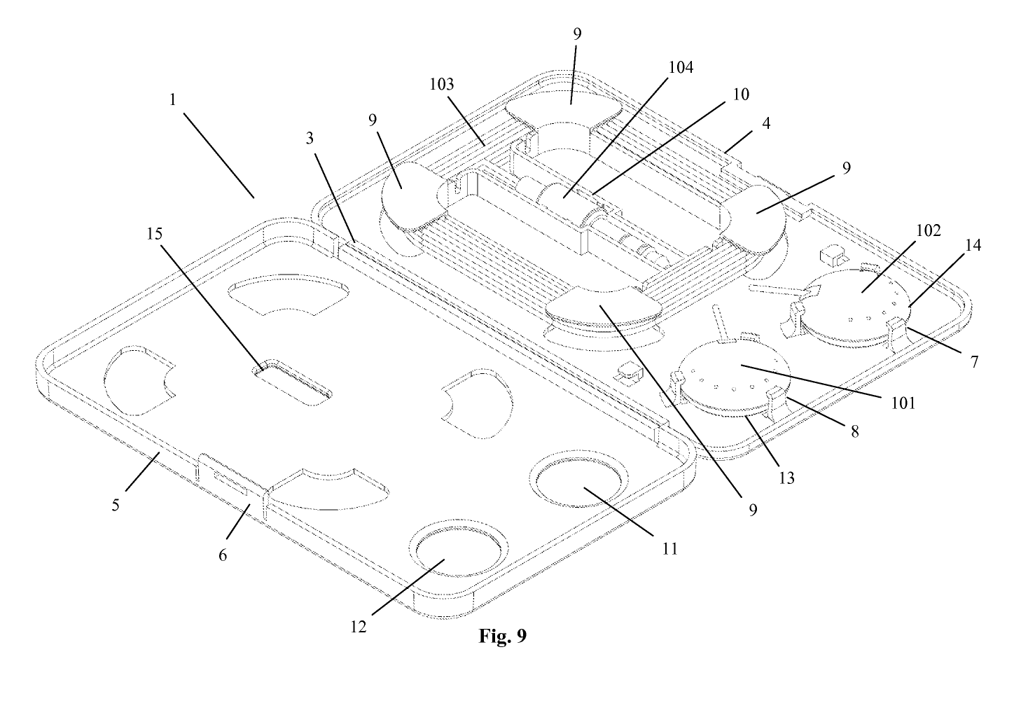

### DETAILED DESCRIPTION OF THE PREFERRED EMBODIMENT

The following description and figures are meant to be illustrative only and not limiting. Other embodiments of this invention will be apparent to those of ordinary skill in the art in view of this description.

The earphone case 1 is a compact and extremely slim case for securely holding a pair of compact earphones 101, 102, their cables 103, and the audio plug 104. In the preferred embodiment shown in the drawings, the earphone case 1 is approximately the dimension of a standard credit card (approximately 86 mm×54 mm) with a thickness approximately equivalent to the depth of an earphone 101, 102. The earphone case 1 is particularly adapted for use with the earphones designed by the applicant which is the subject of U.S. design patent no. D625,709 with an approximate depth of 6 mm.

The earphone case 1 is preferably made of a plastic material in the form of a molded one-piece clam-shell 2 with no moving components. The plastic material is preferably selected from materials that is flexible yet has sufficient strength to resist structural damage due to external pressure when placed in a wallet. The earphone case 1 securely encloses and holds a pair of earphones 101, 102 and the 3.5 mm audio plug 104 along with their cables 103 securely wrapped inside the case 2. None of the components of the earphones 101, 102, 103, 104 will come loose or can be removed from the case 2 without opening the case 2.

In the preferred embodiment, the earphone case 1 comprises of a plastic one-piece clam-shell case 2 with no moving parts. The clam-shell 2 is hinged in the middle 3 with the two sides 4, 5 connected with a flexible strip of plastic material. When folded at the hinge 3, the opposite sides 4, 5 of the clam-shell 2 are snapped closed by a latch 6. The latch 6 can be opened and closed by flexing the latch 6. Two holders 7, 8 are provided inside and near one end of the case 2 to retain and hold the two earphones 101, 102. The cables 103 from the two earphones 101, 102 are wound around slim spacers 9 inside the case 2 near the opposite end of the case 2. A holder 10 is provided near the center of the spacers 9 to retain and hold the 3.5 mm audio plug 104.

Openings 11, 12, 13, 14 are provided on the two opposite sides 4, 5 of the case 2 to enable a portion of both sides of the earphones 101, 102 to be exposed on both sides 4, 5 of the case 2. Earphones are generally round with thicker center portion than near the circumference. The openings 11, 12, 13, 14 are preferably slightly smaller than the diameters of the earphones 101, 102 and have approximately the same contour as the earphones 101, 102 where the openings 11, 12, 13, 14 contact the earphones 101, 102. The earphones 101, 102 will fit snugly and securely within the holders 7, 8 in the case 2 with their front and rear facing center portions protrude from the insides of the case 2 to fit flush with the outsides of the case 2 when the case 2 is closed. In the closed position, the case 2 only has about the same thickness as the thickest portion of the earphones 101, 102. By enlarging the openings 11, 12, 13, 14 in the case 2, the earphones 101, 102 will protrude further to the outside surface of the case 2 and the case thickness can be further reduced to less than that of the depth of the earphones 101, 102. The earphones 101, 102 will still be securely retained within the case 2 as long as the diameter of the openings 11, 12, 13, 14 is smaller than the diameter of the earphones 101, 102. The case 2 must still be opened to remove the earphones 101, 102 from the case 2. Depending on the size and shape of the audio plug 104, optional openings 15, 16 may also be provided for the audio plug 104 on both sides 4, 5 of the case 2 to enable the audio plug 104 to protrude from the insides of the case 2 to fit flush with the outsides of the case 2 on both sides 4, 5 when the case 2 is closed.

The earphone case 1 of the present invention is approximately the size of a conventional credit card and is no thicker than the depth of the earphones 101, 102. The thickness of the case wall is completely eliminated from the determination of the overall thickness of the case 2 since the earphones 101, 102 protrude through the case wall thereby enabling the case 2 to be slimmer than the earphones' depth. The present invention is the slimmest possible case for a pair of compact earphones. The earphone case 1 of the present invention can be carried easily and conveniently in a wallet similar to a conventional credit card.

Although the invention has been described in terms of particular embodiments and applications, one of ordinary skill in the art, in light of this teaching, can generate additional embodiments and modifications without departing from the spirit of or exceeding the scope of the claimed invention. Accordingly, it is to be understood that the drawings and descriptions herein are proffered by way of example to facilitate comprehension of the invention and should not be construed to limit the scope thereof.

1. An earphone case for securely holding a pair of earphones, their cables, and an audio plug comprising:
a case that has two halves that can be opened and closed;
two earphone holders are provided inside said case to retain the pair of earphones wherein said earphone holders are in the form of protrusions that retain the earphones;
one or more spacers are provided inside said case to enable the cables from the two earphones to wrap around said spacers; and
a plug holder is provided inside said case to retain and hold the audio plug;
wherein the earphones, their cables, and the audio plug can only be removed after opening the case.

2. An earphone case as in claim 1, wherein one or more openings are provided through each of the two halves of said case to enable a portion of both sides of the earphones to be exposed through the case.

3. An earphone case as in claim 2, wherein said openings are preferably slightly smaller than a diameter of the earphones and have approximately the same contour as the earphones where the openings contact the earphones.

4. An earphone case as in claim 2, wherein the earphones fit flush with the outsides of the case when the case is closed.

5. And earphone case as in claim 2, wherein an opening is provided for the audio plug through each half of said case to enable the audio plug to protrude from the insides of the case to fit approximately flush with the outsides of the case on both sides when the case is closed.

6. An earphone case as in claim 1, wherein said case is made of a plastic material in the form of a molded one-piece clam-shell.

7. An earphone case as in claim 1, wherein said case is approximately the dimension of a standard credit card with a thickness approximately equivalent to the depth of an earphone.

8. An earphone case as in claim 7, wherein said case is approximately 86 mm wide and 54 mm high with a thickness of approximately 6 mm.

9. An earphone case for securely holding a pair of earphones, their cables, and an audio plug comprising:
a case made of a plastic material in the form of a molded one-piece clam-shell that has two halves that can be opened and closed wherein one or more openings are provided through each of the two halves of said case to enable a portion of both sides of the earphones to be exposed through the case;
two earphone holders are provided inside said case to retain the pair of earphones wherein said earphone holders are in the form of protrusions that retain the earphones;
one or more spacers are provided inside said case to enable the cables from the two earphones to wrap around said spacers; and
a plug holder is provided inside said case to retain and hold the audio plug;
wherein the earphones, their cables, and the audio plug can only be removed after opening the case.

10. An earphone case as in claim 9, wherein said openings are preferably slightly smaller than a diameter of the earphones and have approximately the same contour as the earphones where the openings contact the earphones.

11. An earphone case as in claim 10, wherein the earphones fit flush with the outsides of the case when the case is closed.

12. An earphone case as in claim 9, wherein said case is approximately the dimension of a standard credit card with a thickness approximately equivalent to the depth of an earphone.

13. An earphone case as in claim 12, wherein said case is approximately 86 mm wide and 54 mm high with a thickness of approximately 6 mm.

14. An earphone case as in claim 9, wherein an opening is provided for the audio plug through each half of said case to enable the audio plug to protrude from the insides of the case to fit approximately flush with the outsides of the case on both sides when the case is closed.

15. An earphone case for securely holding a pair of earphones, their cables, and the audio plug comprising:
a case made of a plastic material in the form of a molded one-piece clam-shell that has two halves that can be opened and closed wherein openings are provided through each of the two halves of said case to enable a portion of both sides of the earphones to be exposed through the case and an opening is provided for the audio plug through each half of said case to enable the audio plug to protrude from the insides of the case to fit approximately flush with the outsides of the case on both sides when the case is closed and wherein said case is approximately the dimension of a standard credit card with a thickness approximately equivalent to the depth of the earphone;
two earphone holders are provided inside said case to retain the pair of earphones wherein said earphone holders are in the form of protrusions that retain the earphones;
one or more spacers are provided inside said case to enable the cables from the two earphones to wrap around said spacers; and
a plug holder is provided inside said case to retain and hold the audio plug;
wherein the earphones, their cables, and the audio plug can only be removed after opening the case.

16. An earphone case as in claim 15, wherein said case is approximately 86 mm wide and 54 mm high with a thickness of approximately 6 mm.
